(19) United States
(12) Patent Application Publication
(10) Pub. No.: US 2004/0209450 A1
(43) Pub. Date: Oct. 21, 2004

(54) Method of manufacturing a semiconductor device for reducing resistance of a CoSi2 layer

(76) Inventors: Wan-Yi Liu, Hsinchu (TW); Cheng-Shun Chen, Miaoli (TW)

Correspondence Address: RABIN & Berdo, PC, 1101 14TH STREET, NW, SUITE 500, WASHINGTON, DC, 20005, US

(21) Appl. No.: 10/414,095

(22) Filed: Apr. 16, 2003

(51) Int. Cl. H01L 21/4763

(52) U.S. Cl. 438/592; 438/682

(57) ABSTRACT

A method of manufacturing a semiconductor device for reducing resistance of a CoSi₂ layer is disclosed. First, a cobalt layer is formed on the silicon substrate, and two of the annealing treatments are conducted. The first annealing treatment is used for converting cobalt into a cobalt silicide (CoSi) layer. Next, a cap layer, about 1000 Å to 3000 Å thick, is formed on the CoSi layer, for the purpose of inhibiting re-growth of CoSi grains in the subsequent thermal processes. Then, the CoSi layer is converted into a CoSi₂ layer by the second annealing treatment.

### BACKGROUND OF THE INVENTION

1. Field of the Invention

The invention relates in general to a method of manufacturing a semiconductor device, and more particularly to a method of manufacturing the semiconductor device for reducing resistance of a CoSi₂ layer.

2. Description of the Related Art

In the manufacturing process of semiconductor devices, the low resistance cobalt disilicide (CoSi₂) layer is commonly formed over at the electrical interconnection points, such as formed on the gate electrode (polysilicon), and/or the source/drain regions. Generally, a cobalt layer is formed on the silicon substrate, and two of the annealing treatments are conducted. One annealing treatment is used for diffusing cobalt into the silicon substrate first, and a cobalt silicide (CoSi) layer is thus formed. The other annealing treatment is used for reducing resistance by converting the CoSi layer into a CoSi₂ layer.

FIG. 1A˜FIG. 1D schematically illustrate a conventional method of manufacturing a CoSi₂ layer of a semiconductor device. The source/drain regions 12, gate electrode 14, a gate oxide layer 16 and sidewall spacers 18 are formed on a silicon substrate 10, as shown in FIG. 1A.

Then, a cobalt layer 20 is formed on the silicon substrate 10 by sputtering, as shown in FIG. 1B. A titanium layer or a titanium nitride layer (not shown) may be further formed on the cobalt layer 20, for the purpose of protecting the cobalt from oxidation.

Next, a first annealing treatment is conducted, and the cobalt layer 20 is partially converted into the cobalt silicide (CoSi) layer 22. The unreacted cobalt is denoted as a symbol of 20A, as shown in FIG. 1C. The first annealing treatment is carried out at a temperature ranged from about 450° C. to 550° C. After the first annealing treatment, the unreacted cobalt 20A is removed.

Then, a second annealing treatment is conducted at a higher temperature, within a range of about 750° C. to 880° C., and the cobalt silicide (CoSi) layer 22 is converted into the cobalt disilicide (CoSi₂) layer 23. The resistance of CoSi₂ layer 23 is low so as to reduce the resistance of the source/drain regions 12 and gate electrode 14.

However, the cobalt silicide grains of CoSi layer 22 will re-grow and form large grain size during the second annealing treatment carried out at higher temperature. This CoSi2 with larger grain size will easily to aggregate together during post-high temperature thermal stress. This act or process of gathering the CoSi grains into a larger crystallization is well known as “agglomeration”. Therefore, the CoSi2 layer 23 manufactured according to the traditional method could have several defects, for example, the surface of the CoSi₂ layer 23 is rough, the large crystallization 232 reach the silicon substrate 10 through the source/drain regions 12, and the discontinuous portion 231 of the CoSi₂ layer 23.

As shown in FIG. 1D, the rough surface of the CoSi₂ layer 23 caused by agglomeration decreases the evenness of the CoSi₂ layer 23, which means that the profile of the CoSi₂ layer 23, and the interface between the CoSi₂ layer and the source/drain regions 12 are uneven. If the contact hole (not shown) is formed in an intermediate insulating layer (not shown) on the CoSi₂ layer 23 by etching, it is difficult to control the stop-position of the contact hole, and the substrate 10 could be over-etched. Hence, the current leakage will happen between the substrate 10 and the contact hole. Also, the large crystallization 232 reaching the silicon substrate 10 causes the current leakage after an electric voltage is applied to the semiconductor device. Besides, the discontinuous portion 231 increases the resistance of the CoSi₂ layer 23, and has effect on the performance of device. Moreover, these defections will become more serious after the CoSi₂ layer 23 experiences more thermal treatment in the subsequent manufacturing processes.

Accordingly, there is a need for semiconductor methodology to solve those considerable issues described above.

### SUMMARY OF THE INVENTION

It is therefore an object of the invention to provide a method of manufacturing the semiconductor device so as to increase the evenness of a CoSi₂ layer and reduce resistance of the CoSi₂ layer.

The invention achieves the above-identified objects by providing a method of manufacturing a semiconductor device for reducing resistance of a CoSi₂ layer. First, a silicon substrate is provided, and a cobalt layer is formed thereon. A cobalt silicide (CoSi) layer is formed by a first annealing treatment, and an unreacted cobalt layer (cobalt residue) is then removed by selective etch. Next, a cap layer is formed on the CoSi layer, for the purpose of inhibiting re-growth of CoSi grains in the subsequent thermal processes. Then, the CoSi layer is converted into a CoSi₂ layer by a second annealing treatment. According to the invention, the cap layer can be a silicon oxide layer or a silicon nitride layer, and the thickness thereof is about 1000 Å to 3000 Å.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1A˜FIG. 1D (prior art) schematically illustrate a conventional method of manufacturing a CoSi₂ layer of a semiconductor device; and

FIG. 2A˜FIG. 2E schematically illustrate a method of manufacturing a semiconductor device for reducing resistance of CoSi₂ layer according to the preferred embodiment of the invention.

### DETAILED DESCRIPTION OF THE INVENTION

In the present embodiment of the invention, the drawings used for the illustration only show the major characteristic parts of the semiconductor device in order to avoid obscuring the invention. Accordingly, the specification and the drawing are to be regard as an illustrative sense rather than a restrictive sense.

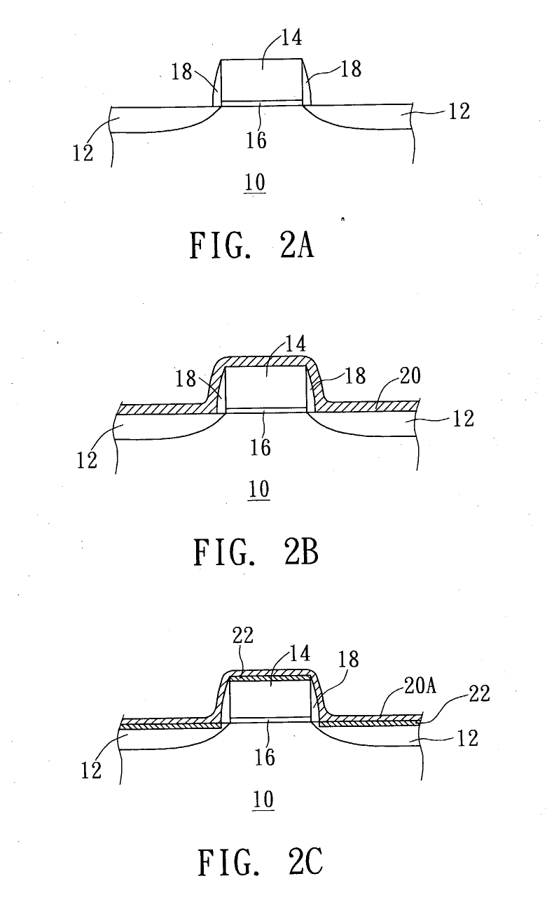

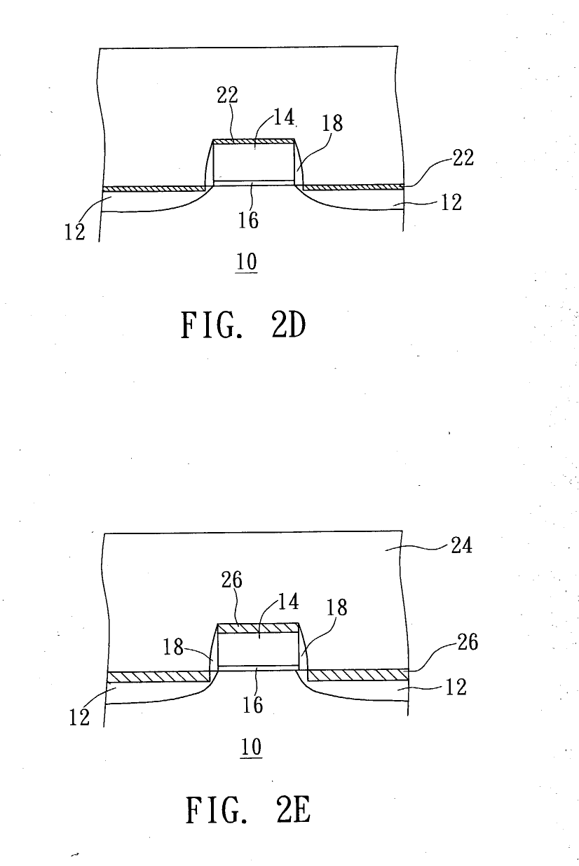

FIG. 2A˜FIG. 2E schematically illustrate a method of manufacturing a semiconductor device for reducing resistance of CoSi₂ layer according to the preferred embodiment of the invention. As shown in FIG. 2A, a silicon substrate 10 is provided. The source/drain regions 12 are formed in the silicon substrate 10, according to the conventional method, to define a channel region. The gate electrode 14, composed of polycrystalline silicon, is formed in the channel region and over a gate oxide layer 16. The sidewall spacers 18, such as silicon oxide, could be formed on the sides of the gate electrode 14.

Then, a cobalt layer 20 is formed on the silicon substrate 10, and the cobalt layer 20 also covers the gate electrode 14, as shown in FIG. 2B. The cobalt layer 20 could be formed by a sputtering method. A titanium layer or a titanium nitride layer (not shown) may be further formed on the cobalt layer 20, for the purpose of protecting the cobalt from oxidation.

Next, a first annealing treatment is conducted to partially convert the cobalt layer 20 into the cobalt silicide (CoSi) layer 22. The bases containing silicon, such as the silicon substrate 10 and the gate electrode 14, are consumed to form the CoSi layer 22. The unreacted cobalt is denoted as a symbol of 20A, as shown in FIG. 2C. The first annealing treatment is carried out at a temperature within a range of about 450° C. to 550° C. for about 30 seconds to 90 seconds.

The unreacted cobalt 20A is removed by selective etch, and a key step of the present invention is then conduced. A cap layer 24 is formed overlying the CoSi layer 22, as shown in FIG. 2D. The cap layer 24 can be a silicon oxide layer or a silicon nitride layer. The thickness of the cap layer 24 is within a range from about 1000 Å to 3000 Å, and preferably about 2000 Å.

Then, a second annealing treatment is conducted to convert the cobalt silicide (CoSi) layer 22 into the cobalt disilicide (CoSi₂) layer 26, as shown in FIG. 2E. The temperature of the second annealing treatment is higher than that of the first annealing treatment. The second annealing treatment is carried out at a temperature within a range of about 750° C. to 880° C. for about 30 seconds to 90 seconds. The cap layer could be removed or not after the CoSi₂ layer 26 has been formed, depending on the device requirement.

In the present invention, the cap layer 24 is used for physically inhibiting the re-growth of CoSi grains in the subsequent thermal processes; therefore, the surface of the CoSi₂ layer 26 of the invention is extremely even, and the conventional problems such as the rough and discontinuous surface of the CoSi₂ layer, and large crystallization can be avoided.

The present invention can be used in any application that it is desired to form a CoSi₂ layer over a substrate composed of silicon.

### Resistance Test

Sheet resistance (Rs) of the samples, fabricated according to the method of the present invention and traditional way, are measured (to provide thermal stress). The test results are listed in Table 1.

TABLE 1

Rs value

| Fabricating method | Max. | Min. | Mean | Std % |
|---|---|---|---|---|
| With cap layer | 8.621 | 7.237 | 7.880 | 6.870 |
| No cap layer | 18.480 | 12.090 | 14.360 | 11.900 |

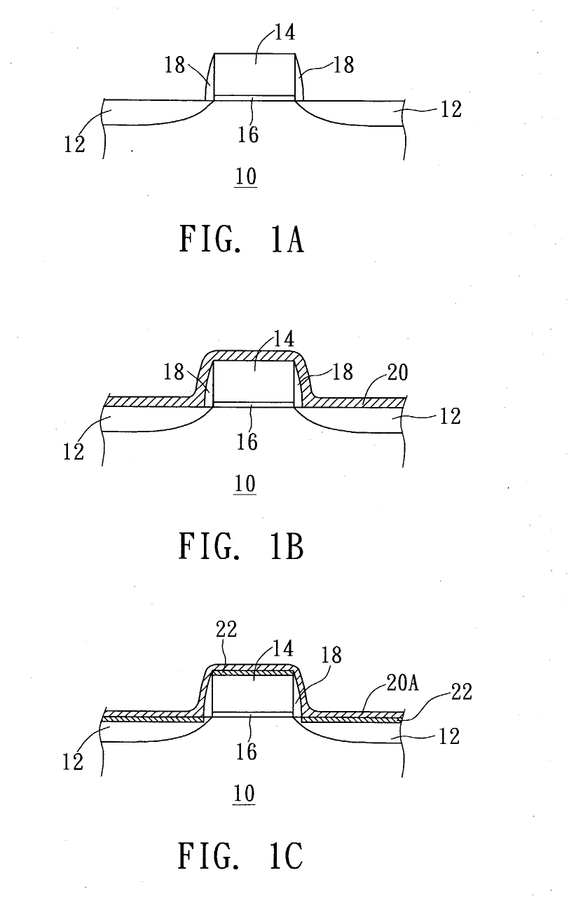

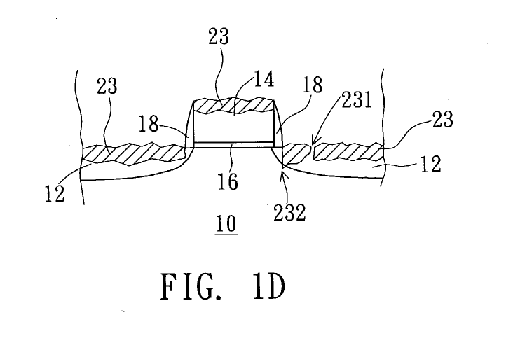

First, the samples fabricated without the cap layer (FIG. 1D) and the samples fabricated with the cap layer (FIG. 2E) are thermally annealed at 950° C. for 360 seconds, and then sheet resistance (Rs) thereof are measure, respectively. The results indicate that the samples fabricated with the cap layer do effectively suppress the sheet resistance increasing. The Rs mean of the samples fabricated with the cap layer is almost half of (that of) the samples fabricated without the cap layer.

Also, sheet resistance (Rs) of the samples fabricated with the cap layer (FIG. 2E) before conducting the Resistance Test are measured, and Rs mean is about 6.6. Compared to Rs mean after thermal annealing at 950° C. for 360 seconds (Rs=7.88), it shows that the samples fabricated with the cap layer do increase thermal stability of CoSi₂ layer.

While the invention has been described by way of examples and in terms of the preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method of manufacturing a semiconductor device for reducing resistance of a CoSi₂ layer, comprising the steps of:
providing a silicon substrate;
forming a cobalt layer on the silicon substrate;
forming a cobalt silicide (CoSi) layer at an interface between the silicon substrate and the cobalt layer by a first annealing treatment, wherein a unreacted cobalt layer is remained on the cobalt silicide layer;
removing the unreacted cobalt layer by selective etch;
forming a cap layer on the cobalt silicide (CoSi) layer; and
converting the cobalt silicide (CoSi) layer into a CoSi₂ layer by a second annealing treatment.

2. The method of manufacturing a semiconductor device according to claim 1, wherein the cap layer is a silicon oxide layer.

3. The method of manufacturing a semiconductor device according to claim 1, wherein the cap layer is a silicon nitride layer.

4. The method of manufacturing a semiconductor device according to claim 1, wherein a thickness of the cap layer is ranged from about 1000 Å to 3000 Å.

5. The method of manufacturing a semiconductor device according to claim 4, wherein a thickness of the cap layer is preferably about 2000 Å.

6. The method of manufacturing a semiconductor device according to claim 1, wherein a temperature of the second annealing treatment is higher than that of the first annealing treatment.

7. The method of manufacturing a semiconductor device according to claim 1, wherein the temperature of the first annealing treatment is ranged from about 450° C. to 550° C.

8. The method of manufacturing a semiconductor device according to claim 7, wherein the first annealing treatment is carried out for about 30 seconds to 90 seconds.

9. The method of manufacturing a semiconductor device according to claim 1, wherein the temperature of the second annealing treatment is ranged from about 750° C. to 880° C.

10. The method of manufacturing a semiconductor device according to claim 9, wherein the second annealing treatment is carried out for about 30 seconds to 90 seconds.

11. The method of manufacturing a semiconductor device according to claim 1, wherein a titanium layer is further formed on the cobalt layer before carrying out the first annealing treatment.

12. The method of manufacturing a semiconductor device according to claim 1 wherein a titanium nitride layer is further formed on the cobalt layer before carrying out the first annealing treatment.

13. The method of manufacturing a semiconductor device according to claim 1, wherein the cap layer is removed after the cobalt silicide layer has been converted into the CoSi₂ layer.

14. A semiconductor device manufactured according to claim 1 comprising:
a silicon substrate;
a CoSi₂ layer formed on the silicon substrate; and
a cap layer formed on the CoSi₂ layer, wherein the cap layer is ranged from about 1000 Å to 3000 Å, and the cap layer is a silicon oxide layer or a silicon nitride layer.

15. A method of manufacturing a semiconductor device for reducing resistance of a CoSi₂ layer, comprising the steps of:
providing a silicon substrate;
forming a cobalt layer on the silicon substrate;
annealing to partially convert the cobalt layer into a cobalt silicide layer at a first heating temperature;
removing a unreacted cobalt layer remained on the cobalt silicide layer by selective etch;
forming a cap layer on the cobalt silicide layer, wherein a thickness of the cap layer is ranged from about 1000 Å to 3000 Å, and the cap layer is a silicon oxide layer or a silicon nitride layer; and
annealing the cobalt silicide layer for being converted into a CoSi₂ layer at a second heating temperature.

16. The method of manufacturing a semiconductor device according to claim 15, wherein a thickness of the cap layer is preferably about 2000 Å.

17. The method of manufacturing a semiconductor device according to claim 15, wherein the second heating temperature is higher than the first heating temperature.

18. The method of manufacturing a semiconductor device according to claim 15, wherein the first heating temperature is ranged from about 450° C. to 550° C.

19. The method of manufacturing a semiconductor device according to claim 18, wherein step of annealing to partially convert the cobalt layer into a cobalt silicide layer is carried out for about 30 seconds to 90 seconds.

20. The method of manufacturing a semiconductor device according to claim 15, wherein the second heating temperature is ranged from about 750° C. to 880° C.

21. The method of manufacturing a semiconductor device according to claim 20, wherein step of annealing the cobalt silicide layer for being converted into a CoSi₂ layer is carried out for about 30 seconds to 90 seconds.

22. The method of manufacturing a semiconductor device according to claim 15, wherein a titanium layer or a titanium nitride layer is further formed on the cobalt layer after forming the cobalt layer.

23. The method of manufacturing a semiconductor device according to claim 15, wherein the cap layer is removed after the cobalt silicide layer has been converted into the CoSi₂ layer.

24. A semiconductor device manufactured according to claim 15 comprising:
a silicon substrate;
a CoSi₂ layer formed on the silicon substrate; and
a cap layer formed on the CoSi₂ layer.
